(19) United States
(12) Patent Application Publication
(10) Pub. No.: US 2007/0096135 A1
(43) Pub. Date: May 3, 2007

(54) Display panel

(76) Inventor: Shoichiro Matsumoto, Ogaki (JP)

Correspondence Address: CANTOR COLBURN, LLP, 55 GRIFFIN ROAD SOUTH, BLOOMFIELD, CT, 06002, US

(21) Appl. No.: 11/541,875

(22) Filed: Oct. 2, 2006

(30) Foreign Application Priority Data
Oct. 3, 2005 (JP) 2005-290423
Sep. 13, 2006 (JP) 2006-248114

(51) Int. Cl. H01L 33/00

(52) U.S. Cl. 257/99

(57) ABSTRACT

A drive current line which supplies power to an EL element includes a branch line which is provided in a display region and a trunk line having a larger cross sectional area than the branch line and which is provided along two or more sides of a peripheral portion of a display region. By providing the trunk line to surround the display region, the percentage of the trunk line along the route of the drive power supply line from a power supply terminal to a pixel is increased. With this structure, a voltage drop of the drive power supply is reduced and uniform power supply to each EL element of the EL panel is realized.

### CROSS-REFERENCE TO RELATED APPLICATIONS

The entire disclosures of Japanese Patent Applications Nos. 2005-290423 and 2006-248114 including specification, claims, drawings, and abstract are incorporated herein by reference.

### BACKGROUND OF THE INVENTION

1. Field of the Invention

The present invention relates to a display panel on which a plurality of pixels are formed in a matrix form, and, in particular, to a line for supplying power to a display element of each pixel..

2. Description of the Related Art

Self-emissive electroluminescence (hereinafter referred to as “EL”) elements, in particular, organic EL elements which use an organic light emitting material in a light emitting layer are known types of current-driven display elements. In particular, because active matrix displays in which a pixel transistor (thin film transistor or “TFT”) is provided in each pixel for controlling, for each pixel, the display element by the transistor are advantageous for realizing a high quality display, much recent development has focused on active matrix displays using an EL element as the display element.

FIG. 1 exemplifies an equivalent circuit of one pixel of an active matrix EL display. A gate line GL is provided along a horizontal scan direction (row direction) of the display and a data line DL and a power supply line PL are provided along a vertical scan direction (column direction). Each pixel comprises a selection transistor Ts which is an n-channel thin film transistor, a storage capacitor Cs, an element driving transistor Td which is a p-channel transistor, and an organic EL element 55. The selection transistor Ts has a drain connected to a data line DL which supplies a data signal to pixels positioned along the vertical scan direction, a gate connected to a gate line GL for selecting pixels positioned along the horizontal scan direction, and a source connected to a gate of the element driving transistor Td.

The element driving transistor Td has a source connected to the power supply line PL and a drain connected to an anode of the organic EL element 55. A cathode of the organic EL element 55 is connected to a cathode power supply CV which is formed common to the pixels. One electrode of the storage capacitor Cs is connected between the gate of the element driving transistor Td and the source of the selection transistor Ts. The other electrode of the storage capacitor Cs is connected to a power supply of a constant voltage such as, for example, ground and a power supply line.

In this circuit, when a selection signal is output and the gate line GL is set to the high (H) level, the selection transistor Ts is switched on, a data signal on the data line DL is supplied via the selection transistor Ts to the storage capacitor Cs and to the gate of the element driving transistor Td, the element driving transistor Td allows a drive current corresponding to the gate signal voltage of the element driving transistor Td to flow from the power supply line PL to the organic EL element 55, and the organic EL element 55 emits light at a luminance corresponding to the drive current. As a result of the storage capacitor Cs storing charges corresponding to the supplied data signal, the gate voltage of the element driving transistor Td is maintained at a voltage corresponding to the data signal for a predetermined period. Therefore, even when the gate line GL is set to the low (L) level, the element driving transistor Td is operated by the stored voltage of the storage capacitor Cs, supply of the drive current is maintained, and the organic EL element 55 continues to emit light.

FIG. 2 is a plan view schematically showing a structure of an organic EL display panel disclosed in Japanese Patent Laid-Open Publication No. 2001-102169 (hereinafter referred to as “Patent Document 1”). In FIG. 2, the outermost solid line indicates a transparent panel substrate 102. A display region 104 shown by a dotted line and in which the above-described pixels are arranged in a matrix form is provided on the panel substrate 102 at a position which is slightly above the center. A horizontal scan driver circuit 106 (hereinafter referred to as “H-related driver”) which outputs a data signal to a data line DL is formed outside of the display region 104 and on one of the sides along the horizontal scan direction of the panel (here, the upper side). In addition, external connection terminals T for supplying a data signal, various timing signals, and power supply to the panel 100 are provided on the other one of the sides along the horizontal scan direction of the panel (here, the lower side). Vertical scan driver circuits (hereinafter referred to as “V-related driver”) 108 which sequentially output a selection signal (gate signal) to the gate line GL are formed outside of the display region 104 and on a right side and on a left side along the vertical scan direction of the panel. Each of the drivers 106 and 108 comprises a thin film transistor or the like which is formed simultaneously formed with the pixel transistor formed in each pixel.

In FIG. 2, the bold solid line extending along the vertical scan direction in the display region 104 represents the power supply line PL. Individual power supply line PL is connected to a wide portion 110 along the horizontal direction which extends along the lower side of the display region 104, and the power supply lines PL as a whole form a comb-like shape. The wide portion 110 is further connected to a line extension portion 112 which is wide and extends along the vertical direction, near a center of the wide portion 110. The wide line extension portion 112 is connected to a corresponding drive power supply terminal T1 among the external connection terminals.

The plurality of the external connection terminals provided at the lower side of the organic EL display panel 100 include, in addition to the drive power supply terminal T1, a cathode terminal T2, a terminal T3 for supplying a timing signal or the like to the V-related driver 108, and a terminal T4 for supplying a timing signal and a data signal to the H-related driver 106.

As described in the above-described Patent Document 1, the power supply line PL connected to the EL element of each pixel via the element driving transistor Td and which supplies a current to the EL element is connected to the wide portion 110 provided along one side of a peripheral portion of the display region and the wide portion 110 is connected to the power supply terminal T1 via an extension line 112 which is also formed in a wide width. The wide portion 110 and wide extension line 112 are employed in order to supply drive current to each power supply line PL with a minimum power loss. Regarding the power supply line PL within the display region connected to each EL element, however, when the line distance from the terminal T1 becomes longer, the voltage drop generated due to the line resistance is increased. Because of this, the EL element of a pixel at a position more distant from the power supply terminal T1 would have a lower light emission luminance compared to the EL element of a pixel at a closer position. Specifically, a slope occurs among light emission luminance of EL elements in the display region, and the difference in the light emission luminance in the display region is recognized as luminance unevenness, resulting in degradation of the display quality as a display. Such a slope in light emission luminance becomes more significant as the area of the display panel, number of pixels, or resolution is increased, hampering efforts to increase the size and resolution of displays.

### SUMMARY OF THE INVENTION

The present invention advantageously ensures the uniformity of power supplied to display elements within the display region.

According to one aspect of the present invention, there is provided a display panel comprising a plurality of pixels arranged in a matrix form in a display region, wherein each pixel comprises a display element which performs a display operation according to power supplied from a power supply line, the power supply line comprises a plurality of branch lines each of which is provided in the display region, is electrically connected to the display element, and supplies power to the display element and a trunk line which is provided on a peripheral portion of the display region and electrically connected to the plurality of the branch lines, the trunk line is formed along at least two sides on the peripheral portion of the display region, and a line width of the trunk line is larger than a line width of the branch line.

According to another aspect of the present invention, there is provided a display panel comprising a plurality of pixels arranged in a matrix form in a display region, wherein each pixel comprises a display element which performs a display operation according to power supplied from a power supply line, the power supply line comprises a plurality of branch lines each of which is provided in the display region, is electrically connected to the display element, and supplies power to the display element and a trunk line which is provided on a peripheral portion of the display region and electrically connected to the plurality of the branch lines, and the trunk line is formed along at least three sides of the peripheral portion of the display region. In the display panel, a line width of the trunk line can be set larger than a line width of the branch line at least on two sides of the peripheral portion of the display region.

According to another aspect of the present invention, there is provided a display panel comprising a plurality of pixels arranged in a matrix form in a display region, wherein each pixel comprises a display element which performs a display operation according to power supplied from a power supply line, the power supply line comprises a plurality of branch lines each of which is provided in the display region, is electrically connected to the display element, and supplies power to the display element and a trunk line which is provided on a peripheral portion of the display region and electrically connected to the plurality of the branch lines, an external connection terminal to which the power supply line is electrically connected is provided on a first side along a vertical scan direction of the display region, the trunk line extends from the first side and is provided at least along a second side along a horizontal scan direction of the display region and a fourth side which opposes the second side with the display region therebetween, and the plurality of the branch lines are connected to the trunk line of the second side and the trunk line of the fourth side and formed along the vertical scan direction.

According to another aspect of the present invention, it is preferable that, in the display panel, the trunk line is provided on the peripheral portion of the display region also on a third side which opposes the first side, on which the external connection terminal is provided, with the display region therebetween, and a cross sectional area of the trunk line which is provided on the third side is larger than a cross sectional area of the trunk line which is provided on the first side.

According to another aspect of the present invention, it is preferable that, in the display panel, the external connection terminal to which the power supply line is electrically connected is provided on a first side along a vertical scan direction of the display region and the trunk line is provided at least from the first side and along a second side along a horizontal scan direction of the display region, and the plurality of branch lines are provided from the second side toward the vertical scan direction.

According to another aspect of the present invention, it is preferable that, in the display panel, the trunk line is provided on the peripheral portion of the display region also on a third side opposing the first side, on which the external connection terminal is provided, with the display region therebetween and on a fourth side which opposes the second side with the display region therebetween, and a cross sectional area of the trunk line which is provided on the third side is larger than a cross sectional area of the trunk line which is provided on the first side.

According to another aspect of the present invention, it is preferable that, in the display panel, a cross sectional area of the trunk line is larger than a cross sectional area of the branch line. The trunk line may be provided along four sides on the peripheral portion of the display region, or the trunk line may be provided surrounding all peripheries of the display region.

According to another aspect of the present invention, it is preferable that, in the display panel, a current-driven electroluminescence element, for example, be used as the display element.

According to another aspect of the present invention, it is preferable that, in the display panel, the trunk line comprises a first line layer which is formed simultaneously with the branch line and with a same material as the branch line and a second line layer which is formed separately from the first line layer and electrically connected to the first line layer.

According to another aspect of the present invention, it is preferable that, in the display panel, the display element comprises a lower electrode which is individual for each pixel and an upper electrode which is common to the pixels, and the second line layer is formed simultaneously with the upper electrode and with a same material as the upper electrode. As the second line layer, it is possible to use a layer which is formed above an insulating layer which is formed above the first line layer in the peripheral region of the display region.

By providing a trunk line electrically connected to a branch line on at least two sides on the peripheral portion of the display region in addition to the branch line provided on the display region and electrically connected to the display element of each pixel, the line resistance of the power supply line of the display panel as a whole can be reduced. In addition, by providing the trunk line on the peripheral portion of the display region, it is possible to increase the line width and the cross sectional area of the trunk line without being limited by factors such as the pixel pitch or the like.

For example, by providing the trunk line on the peripheral portion of the display region along a plurality of sides, power can be supplied from the external connection terminal to the display elements not only from one end within the display region and via a branch line, but also from the other end of the branch line via the trunk line detouring around the peripheral portion of the display region. Thus, it is possible to set the voltage values of both ends to be close to each other even in a configuration in which the branch line is provided only along one direction of the pixel region.

In addition, when the trunk line is provided on a plurality of sides along the peripheral portion of the display region, by increasing the line width and the cross sectional area of a side farther away from the external connection terminal to which the power supply line is electrically connected than the side nearer to the external connection terminal, it is possible to reduce the line resistance at the side which is farther away from the terminal in which the voltage drop is large, to reduce the voltage drop. In other words, it is possible to increase a percentage of the trunk line having a low resistance in a route of the drive power supply line from the external power supply terminal to the pixel, and, thus, the voltage drop can be reduced.

By providing, as the trunk line, a second line layer which is formed separately from a first line layer and which is electrically connected to the first line layer in addition to the first line layer which is formed simultaneously with the branch line and with a same material as the branch line, it is possible to increase the cross sectional area of the trunk line while inhibiting the area along a planar direction of the panel. Thus, the line resistance of the power supply line can be reduced while not reducing the display area.

### BRIEF DESCRIPTION OF THE DRAWINGS

Preferred embodiments of the present invention will be described in detail by reference to the drawings, wherein:

FIG. 1 is a diagram showing an equivalent circuit of a pixel of an organic EL element;

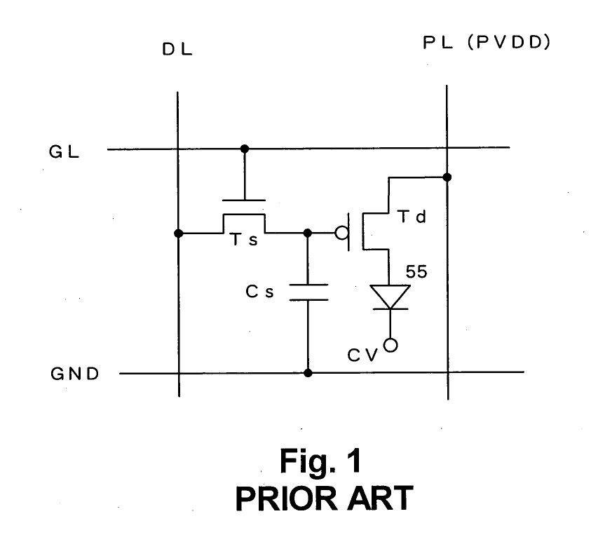

FIG. 2 is a diagram showing a placement of a terminal, a line, a circuit, etc. in an organic EL element of related art;

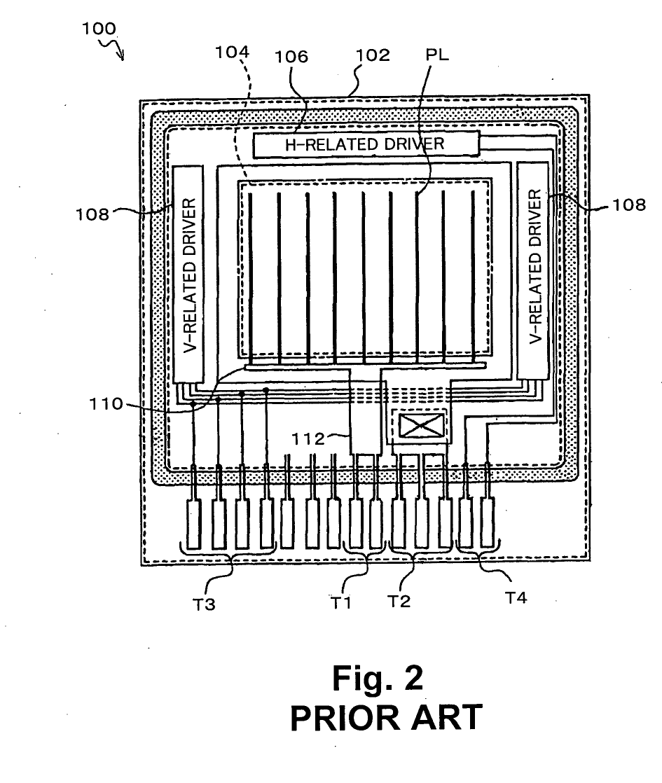

FIG. 3 is a diagram schematically showing a structure of an EL panel according to a first preferred embodiment of the present invention;

FIG. 4 is a conceptual diagram showing an example structure of a drive current line of an EL panel;

FIG. 5 is a conceptual diagram showing another example structure of a drive current line according to the first preferred embodiment of the present invention;

FIG. 6 is a schematic diagram showing a cross section of FIG. 3 along the A-A line;

FIG. 7 is a conceptual diagram showing another example structure of a drive current line according to the first preferred embodiment of the present invention;

FIG. 8 is a diagram for explaining a structure of a drive current line of an EL panel according to a second preferred embodiment of the present invention;

FIG. 9 is a diagram schematically showing a cross sectional structure of a lower side of the panel of FIG. 8; and

FIG. 10 is a diagram showing another structure different from the cross sectional structure of FIG. 9.

### DESCRIPTION OF THE PREFERRED EMBODIMENTS

### First Preferred Embodiment

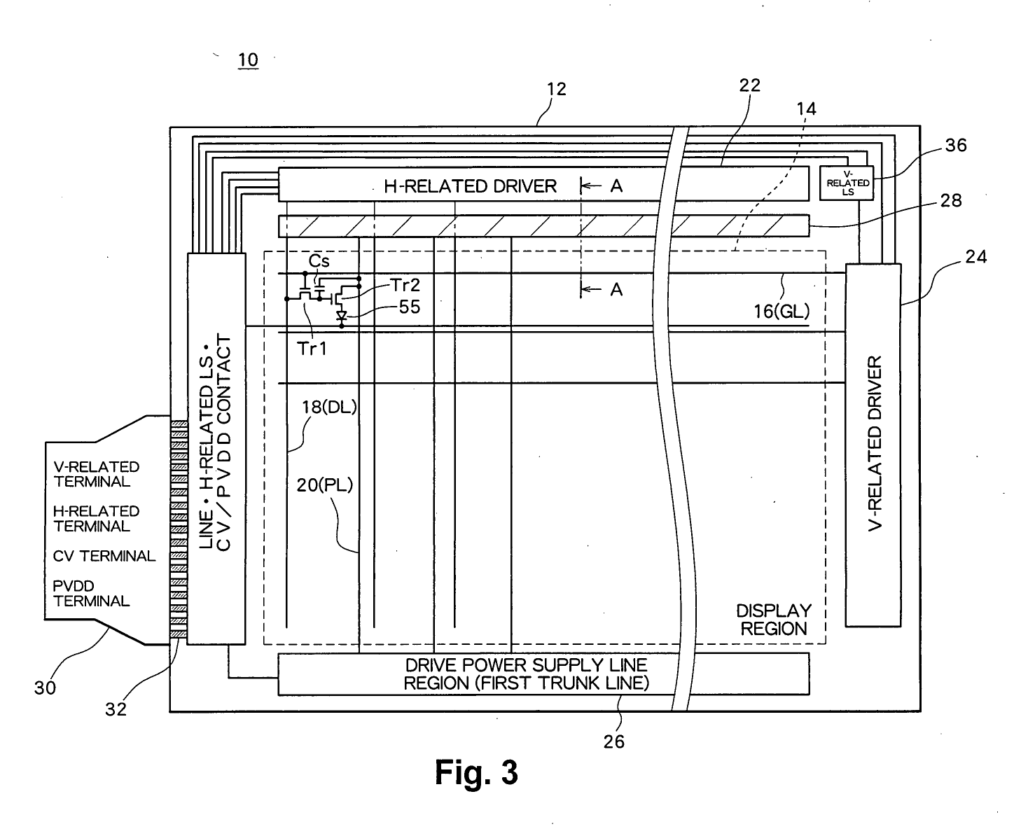

Preferred embodiments of the present invention will now be described referring to the drawings. FIG. 3 schematically shows a structure of a panel portion of an active matrix EL display 10 having an EL element and a thin film transistor for driving the EL element in each pixel, as a display according to a first preferred embodiment of the present invention. An insulating substrate such as glass and plastic is used for a panel substrate 12 and a plurality of pixels are placed in a matrix form in a display region 14 on the panel substrate 12. A gate line 16 (GL) is provided for each row along a horizontal scan direction (row direction) of the matrix in the display region 14 and a selection signal is sequentially output to the gate lines 16. A data line 18 (DL) is provided for each column along a vertical scan direction (column direction) and a data signal is output to the data line 18. A power supply line (PL) 20 is provided for each column similar to the data line 18 and supplies an operation power (in particular, current) (PVDD) to an EL element which is a display element (element to be driven) of each pixel.

Each pixel is formed approximately in a region defined by these lines and comprises, for example, an organic EL element as a display element, a selection transistor Tr1, an element driving transistor Tr2, and a storage capacitor Cs.

The selection transistor Tr1 in this configuration is an n-channel thin film transistor (TFT) and the element driving transistor is a p-channel TFT. The selection transistor Tr1 has a drain connected to a data line 18 for supplying a data voltage to the pixels positioned along the vertical scan direction and a gate connected to a gate line 16 for selecting pixels positioned along one horizontal scan line.

The element driving transistor Tr2 has a gate connected to the source of the selection transistor Tr1, a source connected to a power supply line 20, and a drain connected to a first electrode (in the exemplified configuration, an anode) of the organic EL element 55. In the present embodiment, the first electrode (anode) of the organic EL element 55 is formed in an individual pattern for each pixel and a second electrode (cathode) of the organic EL element 55 is formed common to the pixels and is connected to a common cathode power supply CV. One electrode (first electrode) of the storage capacitor Cs is connected to the gate of the element driving transistor Tr2 and to the source of the selection transistor Tr1, and another electrode (second electrode) of the storage capacitor Cs is maintained at a constant voltage. In the exemplified configuration, the second electrode of the storage capacitor Cs is connected to a power supply line 20 and is maintained at a power supply voltage (PVDD).

In both the selection transistor Tr1 and the element driving transistor Tr2, a semiconductor material is used as an active layer. For example, amorphous silicon and crystalline silicon such as, for example, polycrystalline silicon obtained by polycrystallization through laser annealing may be used in the active layer. In addition, when the crystalline silicon is used in the active layer, an n-channel thin film transistor and a p-channel thin film transistor can be easily formed by doping an n conductive impurity and a p conductive impurity into the active layer using the gate as a mask.

The crystalline silicon thin film transistor can be used not only for the pixel circuit, but also as circuit elements of a peripheral driver circuit for sequentially selecting and controlling the transistors in the pixel circuit. Therefore, in the organic EL display 10 of the present embodiment, a crystalline silicon thin film transistor having a structure similar to that of the pixel transistor is formed on the panel substrate 12, simultaneously with the formation of the pixel transistors, so that a peripheral driver circuit is built in. More specifically, the peripheral driver circuit includes an H-related driver 22 and a V-related driver 24, and, as shown in FIG. 3, the H-related driver 22 is provided in a region at a periphery of the display region 14 along a horizontal scan direction and the V-related driver 24 is provided in a region at a periphery of the display region 14 along the vertical scan direction.

In addition, a drive current trunk line 26 which is a part of a drive current line for supplying a drive current from the drive power supply PVDD to each pixel is provided on a side region of the display region 14 opposing the H-related driver 22 (lower side region of the panel in FIG. 3). Each power supply line (branch line) 20 extending into the display region extends to the formation region of the trunk line 26 and is electrically connected to the trunk line 26. The power supply line 20 and the trunk line 26 form a drive current line (drive power supply line). In the present embodiment, in addition to the trunk line 26 formed on a peripheral opposing the H-related driver 22 with the display region 14, a trunk line 28 (hereinafter referred to as “second trunk line 28”) is formed on a side opposing the trunk line 26 (hereinafter referred to as “first trunk line 26”), that is, the side on which the H-related driver 22 is formed. More specifically, in the exemplified configuration, the second trunk line 28 is provided between the H-related driver 22 and the display region 14, and an end of the power supply line 20 which is opposite to the end connected to the first trunk line 26 is connected to the second trunk line 28.

In the EL display panel according to the present embodiment, external connection terminals 32 connected to an external circuit for supplying various timing signals, data signals, power supplies, etc. to the H-related driver 22, V-related driver 24, drive current lines (20, 26, and 28), or the like are provided on one of two opposing sides along the vertical scan direction of the panel. The present embodiment, however, is not limited to such a configuration, and can be applied to a configuration in which the external connection terminals 32 are formed on other sides such as, for example, a side opposing the H-related driver 22 and along the horizontal scan direction (lower side of the panel in FIG. 3). Regardless of which side the external connection terminals 32 are provided, the trunk line connected to the branch line (power supply line 20) is provided along a plurality of (two or more) sides.

In the example structure of FIG. 3, the external connection terminals 32 are placed on a left side of the panel substrate 12 as described above and is placed opposing the V-related driver 24 with the display region 14 therebetween. A flexible printed circuit (hereinafter referred to as “FPC”) 30 is connected to the external connection terminal 32 and external circuits are connected via the FPC 30. When the external connection terminals 32 are provided on the left side (first side) of the panel substrate 12, a line from an H-related terminal to the H-related driver 22 on which a signal for the H-related driver is supplied, a line from a V-related terminal to a V-related driver 24 on which a signal for the V-related driver is supplied, a line from the PVDD terminal to the drive current trunk line 26, a level shifter (LS) which shifts a voltage level of the clock signal and the start signal, and an extension line from the cathode power supply (CV) terminal to the common cathode are placed along the first side of the panel.

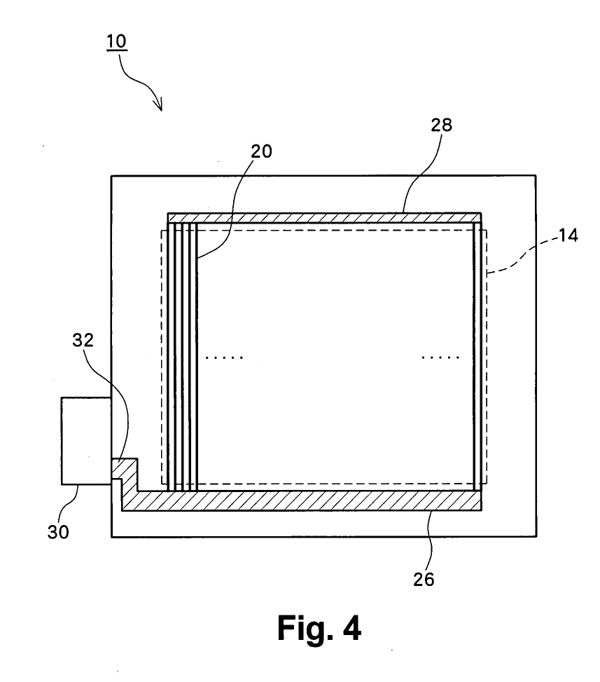

FIG. 4 is a diagram for explaining a structure of the drive current line in a panel portion of the organic EL display 10 of FIG. 3. As described, the first trunk line 26 and the second trunk line 28 of the drive current line are provided on two sides, respectively, along the horizontal scan direction at the periphery of the display region 14 and both ends of the branch line 20 extending along the vertical scan direction are connected to the trunk lines 26 and 28.

In the present embodiment, the cross sectional areas of the first and second trunk lines 26 and 28 are formed to be larger than that of the branch line 20. The cross sectional area of the trunk line is preferably twice or larger that of the branch line 20. When the drive current lines are to be simultaneously formed by patterning a same conductive layer, because the thickness is identical, the cross sectional area of the line is adjusted by adjusting the width of the line (length in a direction perpendicular to the extension direction of the line). In other words, as shown in FIG. 4, each of the first and second trunk lines 26 and 28 is formed with line width which is twice or larger of the line widths of the branch line 20. The branch line 20 is placed in the display region 14 along the vertical scan direction, and, thus, there is a limit to the line width because a wider line width would reduce the display area (aperture ratio). However, because the trunk lines 26 and 28 are formed at a peripheral portion of the display region, the width of the trunk lines 26 and 28 can be widened within an allowable limit of the layout. Thus, even in a situation in which the voltage drop tends to occur because the line width of the branch line 20 cannot be widened, by widening the widths of the trunk lines 26 and 28, the line resistance in the first and second trunk lines 26 and 28 can be reduced. Because the first and second trunk lines 26 and 28 are commonly connected to the plurality of branch lines 20, it is possible to reduce a voltage difference between branch lines and a voltage difference between ends of each branch line. Thus, it is possible to facilitate supply of power, from the corresponding branch line 20, which is similar to the power supplied to a pixel having a short line distance, to a pixel at a position having a long line distance from the external connection terminal 32. Even when conductive layers having different thicknesses or different materials are used for various portions of the drive current line, it is preferable that the line width of the first and second trunk lines 26 and 28 be as wide as possible within an allowable limit of the layout.

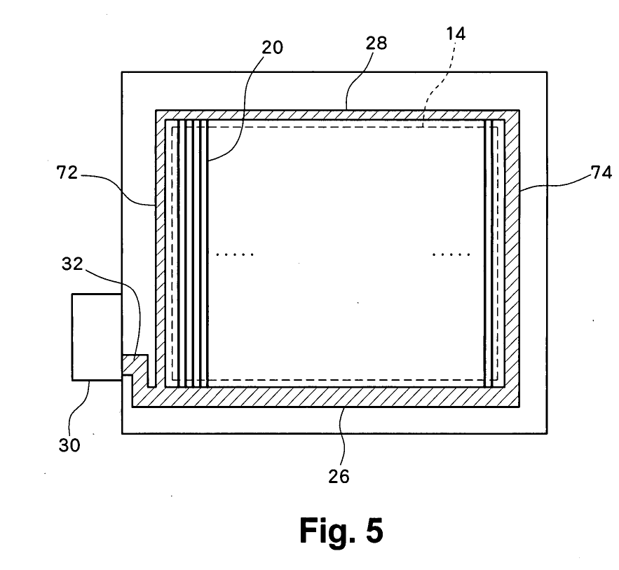

FIG. 5 shows another example structure of a drive current line according to the present embodiment. Structures identical to those in FIG. 4 are assigned the same reference numerals and will not be described again.

FIG. 5 shows an example configuration in which the trunk line is provided along three or more sides of the peripheral portion of the display region 14. More specifically, the trunk lines are provided on all four sides of the peripheral portion of a rectangular display region and are electrically connected to each other. In other words, similar to the drive current line of FIG. 4, the first trunk line 26 and the second trunk line 28 are formed along the lower side and the upper side along the horizontal scan direction of the panel and trunk lines 72 and 74 are formed on two sides along the vertical scan direction of the peripheral portion of the display region 14 connecting the ends of the first and second trunk lines along the horizontal scan direction. The external connection terminals 32 are provided on the left side (first side) of the panel along the vertical scan direction, similar to the configuration shown in FIG. 4. The first trunk line 26 is connected to a portion of the terminals 32 and is provided extending from the first side and along the second side, the second trunk line 28 is provided along a fourth side opposing the first trunk line 26, the third trunk line 72 is provided along the first side similar to the external connection terminal 32, and the fourth trunk line 74 is formed on a third side which opposes the first side with the display region 14 therebetween.

Alternatively, it is also possible to employ a configuration in which only one of the third and fourth trunk lines 72 and 74 is provided. A portion of current supplied from the external connection terminal.32 flows through the third and fourth trunk lines 72 and 74 to the second trunk line 28 at the upper side, and is supplied to corresponding pixels via each branch line 20 in addition to the current from the first trunk line 26. The third and fourth trunk lines 72 and 74 have a larger cross sectional area than the branch line 20 similar to the first and second trunk lines 26 and 28, and preferably have twice or larger cross sectional area. It is preferable that the line width (cross sectional area) of the fourth trunk line 74 be larger than the line width (cross sectional area) of the third trunk line 72. By employing such a relationship, the voltage drop in the fourth trunk line 74 which is provided at a position farther away from the external connection terminal 32 is minimized. On the other hand, the third trunk line 72 is provided at a position close to the terminal 32, and, thus, by setting the line width of the third trunk line 72 to be small, the potential difference with the side of the fourth trunk line 74 is reduced. With this structure, the voltage difference between the voltage applied to a pixel at an upper right corner which is farthest away from the external connection terminal 32 and the voltage applied to the pixel of the lower left corner which is closest to the external connection terminal 32 in the structure of FIG. 5 can be reduced. It is necessary that the cross sectional area of the fourth trunk line 74 be at least larger than the cross sectional area of the second trunk line 28, and that the cross sectional area of the third trunk line 72 be similar to the cross sectional area of the second trunk line 28, although the cross sectional area of the third trunk line 72 may be smaller than the cross sectional area of the second trunk line 28. The cross sectional area of the fourth trunk line 74 is set to be similar to, or smaller then, the cross sectional area of the first trunk line 26.

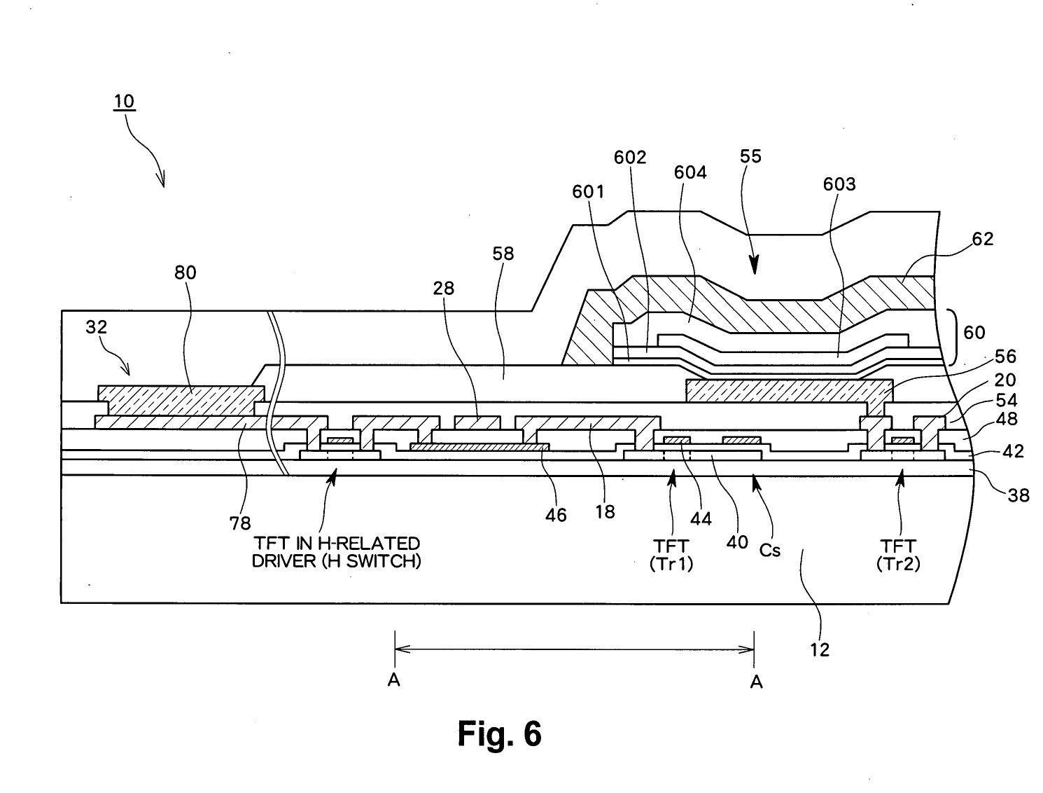

A placement method of the second trunk line 28 provided between the H-related driver 22 and the display region 14 will now be described referring to FIG. 6.

FIG. 6 schematically shows a cross sectional structure of a display panel at a position along the A-A line of FIG. 3. The cross sectional structure of the formation region of the second trunk line 28 is similar to FIG. 6 in the case of the drive line pattern of FIG. 4 and in the case of the drive line pattern of FIG. 5.

A data line 18 extends from the H-related driver 22 along the vertical scan direction. The data line 18 and the branch line 20 of the drive power supply line formed in the display region 14 along the vertical scan direction similar to the data line 18 are formed using the same conductive layer (for example, Al layer). The trunk line can be formed simultaneously and integrally with the branch line 20 through patterning of the same conductive layer as the branch line 20. In this case, if the second trunk line 28 is to be simply provided between the H-related driver 22 and the display region 14, it is necessary to employ a measure to prevent short-circuiting of the second trunk line 28 and the data line 18.

In the present embodiment, as shown in FIG. 6, the output stage TFT within the H-related driver 22, more specifically, the data line 18 extending from a source (or a drain) of an H-switching TFT for sampling and outputting a data signal, is realized by using a separate conductive layer as an intersecting line 46 and placing in a position on a plane intersecting the second trunk line 28. By using a conductive layer which is formed prior to (lower than) the Al layer forming the data line 18 or the like and which is identical to the gate electrode (44 in the figure) of the transistor of the pixel portion and drivers (22 and 24) as the intersecting line 46, it is possible to form the intersecting line 46 without adding a special step. As the gate electrode conductive layer, a refractory metal such as Cr is used.

At an intersecting portion between the data line 18 and the second trunk line 28, by separately placing the data line 18 by the intersecting line 46 rather than the second trunk line 28, a a much higher voltage (for example, +12V), even compared to the other power supplies, other data signals, etc., is applied, and any increase in the line resistance in the drive current line route having a high voltage drop due to the line resistance can be inhibited.

A structure of and a method of manufacturing a TFT and EL element built into the panel shown in FIG. 6 will now be described. A buffer layer 38 having a layered structure of, for example, a SiN film and a SiO₂ film is formed on the panel substrate 12 made of glass or the like. A polycrystalline silicon layer which is formed in an amorphous state and then polycrsytallized through laser annealing or the like is formed above the buffer layer 38. The polycrystalline silicon layer is primarily used for the active layer 40 of the TFT to be built into the panel, and is also used for an electrode of the storage capacitor and for a partial line. A gate insulating layer 42 in which a SiO₂ film and a SiN film are layered in this order is formed covering the entire surface of the substrate including the crystalline silicon layer, the refractory metal layer such as Cr is formed above the gate insulating layer 42, and the metal layer is patterned so that the gate electrode 44 of the TFT having a desired pattern, the gate line which is integral with the gate electrode 44 (reference numeral 16 of FIG. 3), and the intersecting line 46 are formed.

The gate electrode 44 is selectively left above the active layer 40 at a position in which a channel region of the TFT is to be formed and the active layer 40 is doped with an impurity with the gate electrode 44 functioning as a mask. An intrinsic channel region which is not doped with the impurity is formed in a region of the active layer 40 covered by the gate electrode 44, and regions on both sides of the channel region and not covered by the gate electrode are doped with an impurity so that a drain region and a source region are formed. After the impurity doping process, an interlayer insulating layer 48 in which a SiN film and a SiO₂ film are layered in this order is formed covering the entire surface of the substrate.

Then, contact holes are formed though the interlayer insulating layer 48 and a gate insulating layer 42 at positions corresponding to the source and drain regions of the TFT and a contact hole is formed through the interlayer insulating layer 48 at a position of formation of a contact between the intersecting line 46 and the data line 18 at the upper layer. A layered metal conductive layer having a structure comprising layers of Mo, Al, and Mo is formed above the interlayer insulating layer 48 and is patterned to form the data line 18, the power supply line (branch line) 20, and the trunk lines (26, 28, 72, and 74) which are integral with the power supply line 20. The layered structure of Mo, Al, and Mo may also be used for the external connection terminal 32.

Then, a first planarizing insulating layer 54 is formed over an entire surface of the substrate covering these lines using an insulating material made of, for example, an acrylic resin and a contact hole through the first planarizing insulating layer 54 is formed in a region corresponding to the source (or the drain) of the element driving transistor Tr2. A conductive transparent metal oxide layer such as ITO (Indium Tin Oxide) and IZO (Indium Zinc Oxide) is then formed above the first planarizing insulating layer 54, patterned into a desired shape so that a pixel electrode 56 (first electrode of the organic EL element) having an individual pattern for each pixel is formed. Alternatively, it is also possible to form the transparent conductive metal oxide layer also above the Mo/Al/Mo metal terminal layer 78 exposed by removing the first planarizing insulating layer 54 at the terminal portion simultaneously with the formation of the pixel electrode 56. With this structure, by covering the metal terminal layer by a metal oxide layer 80, it is possible to inhibit increase in connection resistance by surface oxidation or the like even when the terminal is exposed to the outside environment.

After the pixel electrode 56 is formed, a second planarizing insulating layer 58 made of an insulating material such as an acrylic resin is formed covering the entire substrate, and, in a region of formation of the pixel electrode 56, an edge portion of the second planarizing insulating layer 58 is removed to form an opening and expose a surface of the pixel electrode 56. A light emitting element layer 60 including an organic light emitting material is layered above the second planarizing insulating layer 58 through vacuum evaporation or the like and a second electrode 62 common to the pixels is formed above the light emitting element layer 60 using Al, an Al alloy, a MgAg alloy, etc. and through, for example, layering by vacuum evaporation.

The light emitting element layer 60 comprises at least a light emitting layer containing an organic compound having a light emitting function, and may have a single layer structure or a multi-layer structure depending on the function of the compound to be used. When the first electrode 56 is an anode and the second electrode 62 opposing the first electrode 56 is a cathode as in the present embodiment, for example, the light emitting element layer 60 may have a layered structure of a hole injection layer 601, a hole transport layer 602, a light emitting layer 603, and an electron transport layer 604, formed in this order from the side of the first electrode.

The charge transport layer and injection layer other than the light emitting layer may be formed common to all pixels. When an emission color of the EL element of each pixel is white and a full-color display is to be realized by obtaining light of R, G, and B using color filters, the light emitting layer 603 of the organic EL element does not need to be formed in an individual pattern for each pixel using a mask even when the light emitting layer 603 is to be formed through vacuum evaporation, and may be formed common to all pixels. When the EL element of each pixel emits corresponding light of R, G, or B, organic light emitting materials different for each emission color needs to be used, and at least the light emitting layer 603 is formed in an individual pattern for each pixel. Although not shown in FIG. 6, the second electrode 62 is connected to the common cathode line extending from the CV terminal on the first side of the panel.

As is clear from the structure of FIG. 6, the third trunk line 72 of FIG. 5 is formed on the first side along the vertical scan direction of the panel. On the first side, the common cathode line extending from the CV terminal only needs to contact the second electrode 62 of the uppermost layer of the EL element. The first planarizing insulating layer 54 and the second planarizing insulating layer 58 are formed between the second electrode 62 and the third trunk line 72, and the second electrode 62 and the third trunk line 72 are insulated. Thus, even when the third trunk line 72 is formed on the first side, there is no need for forming a special three-dimensional intersection structure.

The fourth trunk line 74 formed along the third side of the panel is provided between the V-related driver 24 and the display region 14. However, the gate line 16 extending from the V-related driver 24 and the fourth trunk line 74 are separate conductive layers and the interlayer insulating layer 48 is present between these conductive layers. Therefore, also regarding the fourth trunk line 74, there is no need for forming a special three-dimensional intersection structure, even when the fourth trunk line 74 is formed on the third side.

When, for example, the branch line 20 is formed in a lattice shape in the display region, that is, when the branch line 20 is also laid out along the horizontal scan direction in the display region, it is also possible to omit the second trunk line to be provided between the H-related driver 22 and the display region, and form the trunk lines on three sides including two sides along the vertical scan direction (first and third sides) and a side along the horizontal scan direction (second side).

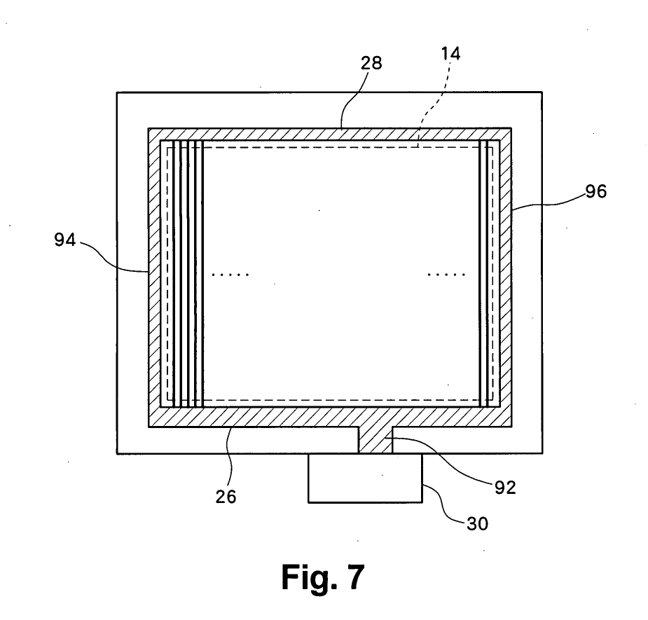

In the above-described layout of the EL panel, a case is described in which the external connection terminals are formed on a side along the vertical scan direction of the panel. However, the present embodiment is not limited to such a configuration, and similar advantages can be obtained by providing external connection terminals 92 on a side along the horizontal scan direction of the panel (lower side in the example configuration of FIG. 7) as shown in FIG. 7.

In this case, the trunk line for supplying power connected to the branch line 20, provided along two or more sides, and formed to have a cross sectional area larger than that of the branch line 20 may be formed, for example, surrounding four sides of the display region 14 at the peripheral portion of the display region 14 as shown in FIG. 7. In other words, in this structure, the first trunk line 26 is formed on a lower side of the panel and along a side closest to the external terminal 92 and the second trunk line 28 is provided on the upper side of the panel, that is, in a region between the H-related driver and the display region. A third trunk line 94 and a fourth trunk line 96 are formed along the left and right sides of the panel (two sides along the vertical scan direction), and the four trunk lines are connected to each other at the four corners. In addition, the display region 14 is surrounded by the four trunk lines.

The line widths (and corresponding cross sectional areas) of the trunk lines 94 and 96 located on the left and right sides can be set equal because the positions from the external connection terminals 92 are close to the center portion along the horizontal scan direction. The line width (and corresponding cross sectional area) of the second trunk line 28 provided on the upper side may be set larger than the third trunk line 94 and the fourth trunk line 96, because the second trunk line 28 is at a position which is farthest away from the terminals. Alternatively, it is also possible to employ a configuration in which the trunk lines are formed only on the upper and lower sides of the panel as shown in FIG. 4.

### Second Preferred Embodiment

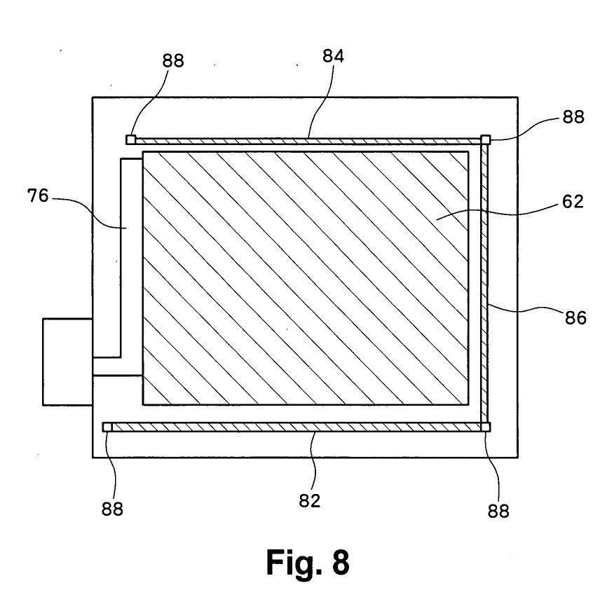

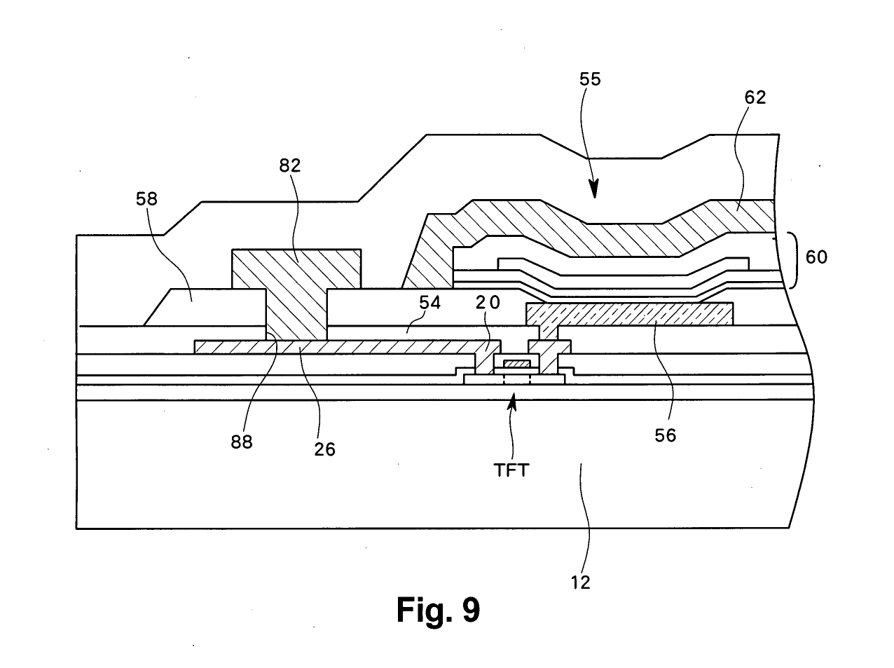

FIG. 8 is a diagram conceptually showing a structure of a drive current line of an EL panel according to a second preferred embodiment of the present invention and FIG. 9 schematically shows a cross sectional structure around a lower side of the panel. Structures identical to those described with reference to the first preferred embodiment are assigned the same reference numerals. In the drive current line of the present embodiment, for example, as shown in FIG. 6, in addition to the trunk lines 26, 28, 72, and 74 (first line layer) of the drive current line formed on the same layer as the data line 18 and the power supply line 20, an auxiliary drive current line (second line layer) is formed using a layer separate from the first line layer. More specifically, auxiliary drive current lines 82, 84, and 86 are formed using a same metal layer as that of the upper electrode of the EL element, that is, the second electrode 62, and are formed at positions which approximately overlap the formation region of the trunk line. In the configuration of FIG. 8, the external connection terminal 32 is placed on one side along the vertical scan direction of the panel similar to FIG. 5, the first auxiliary drive current line 82 is provided in parallel to the lower side of the panel, that is, the first trunk line 26, the second auxiliary current line 84 is provided in parallel to the upper side, that is, the second trunk line 28, and the third auxiliary drive current line 86 is provided on the right side. No auxiliary drive current line is formed on the first side (left side) on which the external connection terminals are placed because the cathode line 76 extending from the CV terminal contacts the second electrode 62 of the EL element on the first side, as previously described. That is, a metal layer (Al) which is identical to the trunk line and the branch line is used for the cathode line 76 and the cathode line 76 contacts the second electrode 62 made of a metal layer identical to that for the auxiliary drive current line. By providing the lines further outside (on a side of outer edge of the panel) of the formation region of the CV line 76, it is possible to form the auxiliary drive current line also on the first side. A contact hole 88 for connecting these auxiliary drive current lines and the trunk line is provided near a corner of a peripheral portion of the display region 14. It is not necessary that all three of the auxiliary drive current lines shown in FIG. 8 be provided, and the auxiliary drive current lines can be selectively provided as necessary.

The position of the contact hole 88 can also be suitably changed. As shown in FIG. 8, the contact hole 88 is formed by forming an opening through the first and second planarizing insulating layers 54 and 58 formed covering the trunk line (here, first trunk line 26) to expose the trunk line. By using an evaporation mask corresponding to the pattern of the auxiliary drive current line and the second electrode when the second electrode 62 is formed through vacuum evaporation, it is possible to form the auxiliary drive current line simultaneously with the second electrode 62 overlapping the trunk line and the auxiliary drive current line is electrically connected to the trunk line of the lower layer through the contact hole 88. The other auxiliary drive current lines also are formed in a similar manner and are connected to the trunk line. In this manner, by providing the auxiliary drive current line electrically connected to the trunk line using an electrode layer of the EL element separately from the trunk line, it is possible to enlarge the substantial cross sectional area of the trunk line by the auxiliary drive current line without increasing the line width of the trunk line, and, thus, the line resistance of the trunk line can be reduced through the auxiliary drive current line with a high line efficiency. In addition, because the auxiliary drive current line is formed simultaneously with the second electrode of the EL element, it is possible to further reduce the line resistance without adding an additional step to the manufacturing process.

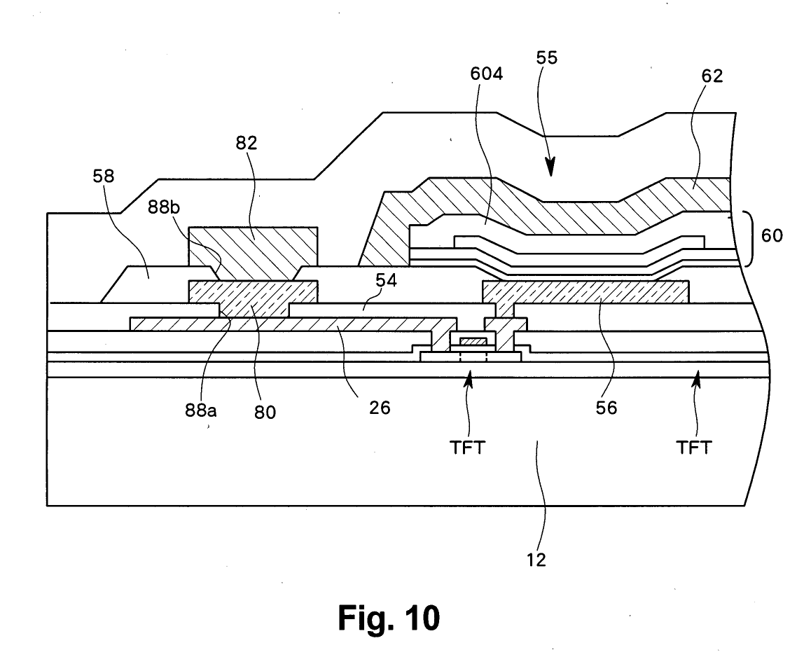

FIG. 10 is a diagram showing an alternative connection method of the auxiliary drive current line and the trunk line shown in FIG. 9. A difference from FIG. 9 is that the auxiliary drive current line and the trunk line are connected via a transparent conductive metal oxide layer 80 in FIG. 10. A contact hole 88a is formed at a peripheral position of the display region 14 of the first planarizing insulating layer 54 prior to the formation of the first electrode (pixel electrode) 56 of the EL element on the first planarizing insulating layer 54. Then, ITO or the like is layered, and the transparent conductive metal oxide layer 80 is selectively left on the formation region of the contact hole 88a simultaneously with the patterning of the ITO or the like in a shape corresponding to the pixel electrode of the organic EL element. The second planarizing insulating layer 58 is formed, a contact hole 88b is formed at a position identical to that of the contact hole 88a, and a metal evaporation layer which forms the auxiliary drive current line is formed simultaneously with the formation of the second electrode 62. The auxiliary drive current line 82 is connected to the trunk line 26 via the transparent conductive metal oxide layer 80. The contact holes 88, 88a, and 88b shown in FIGS. 9 and 10 may be of any shape including a circle, a quadrangle, etc.

As shown in FIG. 7, even when the external connection terminal 92 is formed on another side of the panel (for example, lower side), the advantages of the present invention can be obtained by forming the auxiliary drive current line overlapping the trunk line in a similar manner using a material layer for the second electrode of the EL element or the like as in the second preferred embodiment of the present invention.

What is claimed is:

1. A display panel comprising a plurality of pixels arranged in a matrix form in a display region, wherein
each pixel comprises a display element which performs a display operation according to power supplied from a power supply line;
the power supply line comprises:
a plurality of branch lines each of which is provided in the display region, is electrically connected to the display element, and supplies power to the display element, and
a trunk line which is provided on a peripheral portion of the display region and electrically connected to the plurality of the branch lines; and
the trunk line is formed along at least two sides on the peripheral portion of the display region and a line width of the trunk line is larger than a line width of the branch line.

2. A display panel according to claim 1, wherein
the trunk line is provided along four sides on the peripheral portion of the display region.

3. A display panel according to claim 1, wherein,
the trunk line is provided surrounding all peripheries of the display region.

4. A display panel according to claim 1, wherein
a cross sectional area of the trunk line is larger than a cross sectional area of the branch line.

5. A display panel according to claim 1, wherein
a cross sectional area of the trunk line is at least twice a cross sectional area of the branch line.

6. A display panel according to claim 1, wherein
the display element is a current-driven electroluminescence element.

7. A display panel according to claim 1, wherein
the trunk line comprises a first line layer which is formed simultaneously with the branch line and with a same material as the branch line and a second line layer which is formed separately from the first line layer and electrically connected to the first line layer.

8. A display panel according to claim 7, wherein
the display element comprises a lower electrode which is individual for each pixel and an upper electrode which is common to the pixels, and
the second line layer is formed simultaneously with the upper electrode and with a same material as the upper electrode.

9. A display panel according to claim 8, wherein
the second line layer is formed in the peripheral region of the display region above an insulating layer which is formed above the first line layer.

10. A display panel comprising a plurality of pixels arranged in a matrix form in a display region, wherein
each pixel comprises a display element which performs a display operation according to power supplied from a power supply line;
the power supply line comprises:
a plurality of branch lines each of which is provided in the display region, is electrically connected to the display element, and supplies power to the display element, and
a trunk line which is provided on a peripheral portion of the display region and electrically connected to the plurality of the branch lines; and
the trunk line is formed along at least three sides of the peripheral portion of the display region.

11. A display panel according to claim 10, wherein
a line width of the trunk line is larger than a line width of the branch line at least on two sides of the peripheral portion of the display region.

12. A display panel according to claim 10, wherein
the trunk line is provided along four sides on the peripheral portion of the display region.

13. A display panel according to claim 10, wherein
the trunk line is provided surrounding all peripheries of the display region.

14. A display panel according to claim 10, wherein
a cross sectional area of the trunk line is larger than a cross sectional area of the branch line.

15. A display panel according to claim 10, wherein
a cross sectional area of the trunk line is at least twice a cross sectional area of the branch line.

16. A display panel according to claim 10, wherein
the display element is a current-driven electroluminescence element.

17. A display panel according to claim 10, wherein
the trunk line comprises a first line layer which is formed simultaneously with the branch line and with a same material as the branch line and a second line layer which is formed separately from the first line layer and electrically connected to the first line layer.

18. A display panel according to claim 17, wherein
the display element comprises a lower electrode which is individual for each pixel and an upper electrode which is common to the pixels, and
the second line layer is formed simultaneously with the upper electrode and with a same material as the upper electrode.

19. A display panel according to claim 18, wherein
the second line layer is formed in the peripheral region of the display region above an insulating layer which is formed above the first line layer.

20. A display panel comprising a plurality of pixels arranged in a matrix form in a display region, wherein
each pixel comprises a display element which performs a display operation according to power supplied from a power supply line;
the power supply line comprises:
a plurality of branch lines each of which is provided in the display region, is electrically connected to the display element, and supplies power to the display element, and
a trunk line which is provided on a peripheral portion of the display region and electrically connected to the plurality of the branch lines;
an external connection terminal to which the power supply line is electrically connected is provided on a first side along a vertical scan direction of the display region:
the trunk line extends from the first side and is provided at least along a second side along a horizontal scan direction of the display region and a fourth side which opposes the second side with the display region therebetween; and
the plurality of the branch lines are connected to the trunk line of the second side and the trunk line of the fourth side and formed along the vertical scan direction.

21. A display panel according to claim 20, wherein
the trunk line is provided on the peripheral portion of the display region also on a third side which opposes the first side, on which the external connection terminal is provided, with the display region therebetween, and
a cross sectional area of the trunk line which is provided on the third side is larger than a cross sectional area of the trunk line which is provided on the first side.

22. A display panel according to claim 20, wherein
a cross sectional area of the trunk line is larger than a cross sectional area of the branch line.

23. A display panel according to claim 20, wherein
a cross sectional area of the trunk line is at least twice a cross sectional area of the branch line.

24. A display panel according to claim 20, wherein
the display element is a current-driven electroluminescence element.

25. A display panel according to claim 20, wherein
the trunk line comprises a first line layer which is formed simultaneously with the branch line and with a same material as the branch line and a second line layer which is formed separately from the first line layer and electrically connected to the first line layer.

26. A display panel according to claim 25, wherein
the display element comprises a lower electrode which is individual for each pixel and an upper electrode which is common to the pixels, and
the second line layer is formed simultaneously with the upper electrode and with a same material as the upper electrode.

27. A display panel according to claim 26, wherein
the second line layer is formed in the peripheral region of the display region above an insulating layer which is formed above the first line layer.
